(19) United States
(12) Patent Application Publication
(10) Pub. No.: US 2023/0175135 A1
(43) Pub. Date: Jun. 8, 2023

(54) Center Thermocouple Probe With Leak Detection

(71) Applicant: Conax Technologies, Buffalo, NY (US)

(72) Inventor: Scott M. KROON, Orchard Park, NY (US)

(21) Appl. No.: 18/075,998

(22) Filed: Dec. 6, 2022

Related U.S. Application Data
(60) Provisional application No. 63/286,544, filed on Dec. 6, 2021.

(51) Int. Cl. C23C 16/46; H01L 21/67; C23C 16/52

(52) U.S. Cl. CPC C23C 16/46; C23C 16/52; H01L 21/67248

(57) ABSTRACT

An improved thermocouple of the type contained in a sleeve having a closed distal end and an open proximal end through which the thermocouple leads pass, the improvement comprising a closed, vented cap for substantially closing the open end of the sleeve, the cap having a vent for accommodating a sampling tube for taking samples of gas at the open proximal end of the sleeve, and preferably allowing atmospheric air to replace the gas removed from the interior of the cap through the sampling tube.

### CROSS-REFERENCED APPLICATION

This application claims priority to U.S. provisional application Serial No. 63/286,544 filed on Dec. 6, 2019. The disclosure of the above-referenced application is incorporated herein by reference in its entirety.

### FIELD

This invention relates to thermocouples, and in particular to thermocouples adapted for service in harsh environments like the CVD reactors used in the production of silicon wafers.

### BACKGROUND

This section provides background information related to the present disclosure which is not necessarily prior art.

Temperature control can be vital to many production processes, such as the production of silicon wafers in CVD reactors. Thermocouples are frequently used to monitor the temperature in such harsh environments, however because of the harsh environment these thermocouples can have short lives. Various coatings have been developed to protect thermocouples in these harsh environments, and they are useful in extending the service life. However, in the corrosive environment in which many of these coated thermocouples operate, even coated thermocouple can still fail, and when they do, they provide false temperature information to the system controller that can damage the wafers being produced, allow contaminants to enter the system, and even damage the production equipment.

### SUMMARY

This section provides a general summary of the disclosure, and is not a comprehensive disclosure of its full scope or all of its features.

Embodiments of the present invention provide a method and apparatus for collecting gases from the proximal of the center thermocouples that are indicative of future failure of the thermocouple. Generally, a center thermocouple is disposed in a protective sleeve having a closed distal end extending inside the reaction chamber in which the thermocouple is disposed and a proximal end extending outside the reaction chamber, from which the wire leads from the thermocouple extend. As the protective sleeve degrades, gases from the reaction chamber (e.g., hydrogen) penetrate the sleeve and can be detected. Their presences is an indication of future failure. Embodiments of the present invention provide a vented cap with a sampling tube so that sample can be drawn from the distal end fo the thermocouple sleeve, and analyzed. The cap is preferably vented so that sample of gas from the distal end of the tube can be drawn to a detector, with atmospheric gases forming a small continuous flow through the tube to the detector. If the cap is not vented, there are often enough “leaks” in the connection with the cap to provide replacement air to allow adequate sampling of the gases at the proximal end of the thermocouple sheath.

In the preferred embodiment, a locking fitting is provided around the distal end of the thermocouple sleeve, and a vented sampling cap is provided to engage the locking fitting. In the most preferred embodiment the vented sampling cap can threadedly engage the locking fitting. A sampling tube extends from the interior of the cap. A lead wire passage likewise extends through the cap, to accommodate the lead wires from the thermocouple. This passage preferably also allows atmospheric air into the cap so that gas samples can be withdrawn from the interior of the cap through the sampling tube.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a side elevation view of a center thermocouple of the prior art;

FIG. 2 is a longitudinal cross-sectional view of the center thermocouple of FIG. 1;

FIG. 3 is a top plan view of a center thermocouple and vented sampling cap according to the principles of this disclosure;

FIG. 4 is a longitudinal cross-sectional view of the center thermocouple and vented sampling cap of FIG. 3. Take long the plane of line 4-4 in FIG. 3;

FIG. 5 is a side elevation view of the center thermocouple and vented sampling cap of FIG. 3;

FIG. 6 is a bottom plan view of the center thermocouple and vented sampling cap, taken along the plane of line 6-6 in FIG. 5;

FIG. 7 is an enlarged cross-sectional view of the distal end of the center thermocouple and vented sampling cap, as shown in FIG. 4;

FIG. 8A is a side elevation view of a vented sampling cap in accordance with a preferred embodiment of this disclosure;

FIG. 8B is a partial cross-sectional view of the cap, taken along the plane of line AA in FIG. 8A;

FIG. 8C is an end elevation view of the cap; and

FIG. 8D is a side elevation view of the cap opposite the side shown in FIG. 8A..

Corresponding reference numerals indicate corresponding parts throughout the several views of the drawings.

### DETAILED DESCRIPTION

Example embodiments will now be described more fully with reference to the accompanying drawings.

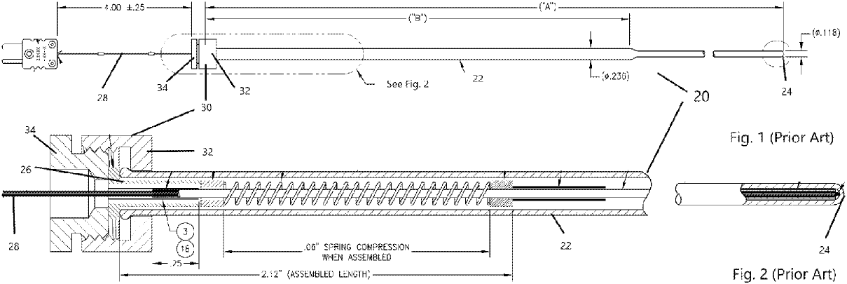

A conventional center thermocouple assembly is indicated generally as 20 in FIGS. 1 and 2. The actual thermocouple itself is s disposed in a protective sleeve 22 having a closed distal end 24 that can be disposed inside a reaction chamber in which the thermocouple is used, and an open proximal end 26 disposed outside the reaction chamber. Lead wires 28 extend from the thermocouple through the open proximal end 26 of the sleeve 22. A two part fitting 30 comprising a female part 32 and a male part 34 engage the distal end of the sleeve 22. The lead wires 28 extend through and out the two-part fitting , from which the wire leads 28 from the thermocouple extend.

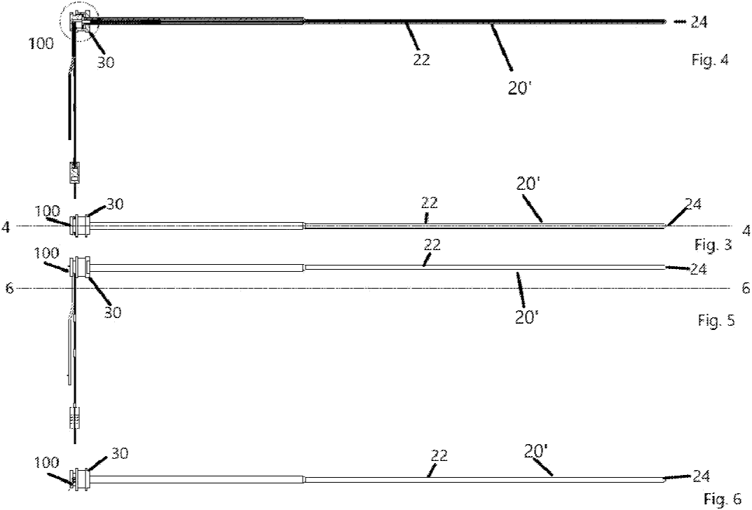

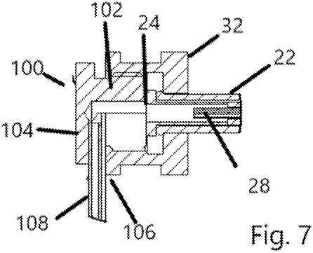

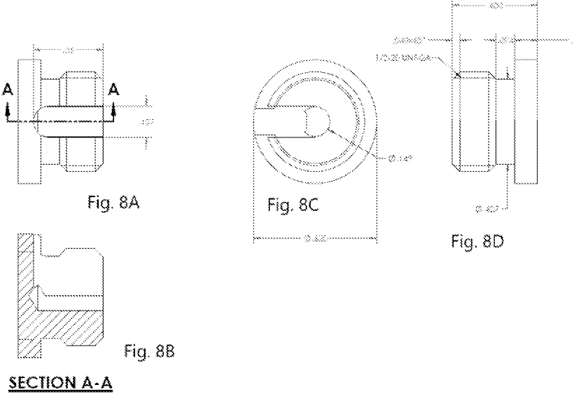

An embodiment of a center thermocouple In accordance with the principles of this disclosure is indicated generally as 20′ in FIGS. 3 - 7. Thermocouple 20′ is generally similar in construction to thermocouple 20, with corresponding structures identified with corresponding reference numerals. However thermocouple 20′ comprises a vented cap 100 in place of male part 34. The vented cap 100 has a threaded barrel portion 102 that is adapted to threadedly engage the female part 32, and a closed back 104. The cap 100 also has a vent 106 extending transversely through the barrel portion 102. The vent 106 accommodates a sample tube 108 that can be connected to a gas sampler. The vent 106 is preferably large enough to accommodate the lead wires 28. The sample tube 106 and the lead wires 28 preferably do not completely occlude the vent 106, so that as sample tube 108 withdraws gas from the interior of the vented cap 100, it is replaced with atmospheric gas through the vent 106. However in some embodiments the sample tube 106 and the lead wires 28 may substantially or completely occlude the vent 106. In these embodiments, “leaks” between the cap 100 and the female part 32 provide replacement air as sample tube 108 withdraws gas from the interior of the vented cap 100.

This vented cap 100 allows sufficient concentration of gases from the open end of the sleeve 22, that imminent failure of the sleeve 22 can be detected. Without the concentrating effect of the closed but vented cap 100, gases indicative of imminent failure of the sleeve have not been detectable.

### Operation

In operation, a thermocouple is provided with a vented cap 100, and the sample tube 108 is connected to a gas monitor. Hydrogen is a component of many CVD processes, process, and when the sheath 22 of the thermocouple begins to fail, hydrogen reports to the proximal end of the sheath. The gas at the proximal end of the sheath can be sampled through tube 108, and when excess hydrogen is detected, appropriate action can be taken -typically replacing the thermocouple. In the most preferred embodiment, the vent 106 allows sufficient replacement gas to penetrate into the cap to replace the gas removed in sampling. In other embodiment, the vent 106 is substantially occluded by tube 106 and the lead wires 28 from the thermocouple, but in most instances there are sufficient “leaks” to provide sufficient replacement air to enter the cap to allow adequate sampling. Even if there aren’t sufficient leaks in the connection with the cap 100, when leaks in the sheath 22 occur, sample gas can be withdrawn via the tube 108. Of course other process gases could be detected instead of or in addition to hydrogen to indicate failure of the thermocouple, and in particular the thermocouple sheath.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. An improved thermocouple of the type contained in a sleeve having a closed distal end and an open proximal end through which the thermocouple leads pass, the improvement comprising a closed, vented cap for substantially closing the open end of the sleeve, the cap having a vent for accommodating a sampling tube for taking samples of gas at the open proximal end of the sleeve, and allowing atmospheric air to replace the gas removed from the interior of the cap through the sampling tube.

2. The improved thermocouple according to claim 1, wherein the cap is threaded to threadedly engage a female fitting surrounding the distal end of the sleeve.

3. The improved thermocouple according to claim 1 wherein the vent in the cap is large enough to accommodate the lead wires from the thermocouple.

4. A two part fitting for the distal end a thermocouple assembly of the type comprising a thermocouple disposed in a sleeve having a closed distal end adapted to be disposed inside a reactor vessel, and an open proximal end adapted to be disposed outside the reactor vessel, the fitting comprising a first female part surrounding the open distal end of the sleeve, and a vented cap adapted to fit in the female part, for substantially closing the open end of the sleeve, the cap having a vent for accommodating a sampling tube for taking samples of gas at the open proximal end of the sleeve, and allowing atmospheric air to replace the gas removed from the interior of the cap through the sampling tube.

5. The two part fitting according to claim 4, wherein the cap is threaded to threadedly engage the female part surrounding the distal end of the sleeve.

6. The two part fitting according to claim 4 wherein the vent in the cap is large enough to accommodate the lead wires from the thermocouple.

7. A vented cap for a female fitting surrounding the the distal end a thermocouple assembly of the type comprising a thermocouple disposed in a sleeve having a closed distal end adapted to be disposed inside a reactor vessel, and an open proximal end adapted to be disposed outside the reactor vessel, the vented cap adapted to fit in the female part, for substantially closing the open end of the sleeve, the cap having a vent for accommodating a sampling tube for taking samples of gas at the open proximal end of the sleeve, and allowing atmospheric air to replace the gas removed from the interior of the cap through the sampling tube.

8. The two part fitting according to claim 4, wherein the cap is threaded to threadedly engage the female part surrounding the distal end of the sleeve.

9. The two part fitting according to claim 4 wherein the vent in the cap is large enough to accommodate the lead wires from the thermocouple.
